(19) United States
(12) Patent Application Publication
(10) Pub. No.: US 2024/0243138 A1
(43) Pub. Date: Jul. 18, 2024

(54) DISPLAY DEVICE

(71) Applicant: Samsung Display Co., LTD., Yongin-si (KR)

(72) Inventors: Hyun Eok SHIN, Yongin-si (KR); Joon Yong PARK, Yongin-si (KR)

(73) Assignee: Samsung Display Co., LTD., Yongin-si (KR)

(21) Appl. No.: 18/519,386

(22) Filed: Nov. 27, 2023

(30) Foreign Application Priority Data
Jan. 13, 2023 (KR) 10-2023-0005655

(51) Int. Cl. H01L 27/12; H01L 25/075; H01L 25/16; H01L 33/38; H01L 33/62

(52) U.S. Cl. CPC H01L 27/124; H01L 25/0753; H01L 25/167; H01L 27/1225; H01L 33/382; H01L 33/62

(57) ABSTRACT

A display device according to an embodiment includes a transistor disposed on a substrate, a first conductive layer electrically connected to the transistor, a first metal layer electrically connected to the first conductive layer, a first electrode electrically connected to the first metal layer, and an emission layer electrically connected to the first electrode. The first metal layer includes a first layer including Zn-ITO, a second layer including Ag, and a third layer including Zn-ITO.

### CROSS-REFERENCE TO RELATED APPLICATION

This application claims priority to and the benefit of Korean Patent Application No. 10-2023-0005655 under 35 U.S.C. § 119, filed on Jan. 13, 2023, in the Korean Intellectual Property Office (KIPO), the entire contents of which are incorporated herein by reference.

### BACKGROUND

### 1. Technical Field

The disclosure relates to a display device.

### 2. Description of the Related Art

A light emitting element is an element in which holes supplied from an anode and electrons supplied from a cathode are combined in an emission layer to form excitons, and light is emitted while the excitons are stabilized.

The light emitting element has several merits such as a wide viewing angle, a fast response speed, a thin thickness, and lower power consumption such that the light emitting diode is widely applied to various electrical and electronic devices such as a television, a monitor, a mobile phone, etc.

The above information disclosed in this Background section is only for enhancement of understanding of the background of the disclosure, and therefore it may contain information that does not form the prior art that is already known in this country to a person of ordinary skill in the art.

### SUMMARY

The disclosure has been made in an effort to provide a display device including a first metal layer with high reflectivity and an excellent interface contact characteristic.

According to an embodiment of the disclosure, a display device may include a transistor disposed on a substrate, a first conductive layer electrically connected to the transistor, a first metal layer electrically connected to the first conductive layer, a first electrode electrically connected to the first metal layer, and an emission layer electrically connected to the first electrode. The first metal layer may include a first layer including Zn-ITO, a second layer including Ag, and a third layer including Zn-ITO.

The display device may include a display area and a pad region, and the first conductive layer, the first metal layer, and the first electrode may contact each other in the pad region.

The first conductive layer may include a first layer including titanium and a second layer including copper, and the second layer of the first conductive layer may contact the first layer of the first metal layer.

The first conductive layer may include a first layer including titanium, a second layer including copper, and a third layer of the first conductive layer may contact the first layer of the first metal layer.

The first electrode may include an indium tin oxide, and the third layer of the first metal layer may contact the first electrode.

The second layer of the first metal layer may be thicker than the first layer of the first metal layer and the third layer of the first metal layer in a thickness direction of the substrate.

A thickness of the first layer of the first metal layer may be in a range of about 50 Å to about 300 Å in a thickness direction of the substrate.

A thickness of the second layer of the first metal layer may be in a range of about 500 Å to about 2000 Å in a thickness direction of the substrate.

A thickness of the third layer of the first metal layer may be in a range of about 50 Å to about 300 Å in the thickness direction.

A content of Zn included in Zn-ITO of the first layer and the third layer may be equal to or greater than about 10 at %.

A content of Zn included in Zn-ITO of the first layer and the third layer may be in a range of about 18 at % to about 20 at %.

Zn-ITO included in the first layer and the third layer may be amorphous.

Zn-ITO included in the first metal layer may be amorphous in case that a heat treatment of about 250° C. is performed.

The first metal layer may not be etched by TMAH and KOH.

A reflectivity of the first metal layer on a wavelength in a range of about 400 nm to about 800 nm may be equal to or greater than about 80%.

The emission layer may include a nanorod.

The transistor may include a semiconductor layer and a gate electrode. The display device may further include a second conductive layer disposed between the semiconductor layer and the first conductive layer and electrically connecting the semiconductor layer and the first conductive layer.

The display device may further include a cell barrier disposed between the first conductive layer and the first metal layer. The cell barrier may include an opening overlapping the emission layer in a plan view.

Light emitted by the emission layer may be reflected by the first metal layer.

The semiconductor layer may include an oxide semiconductor.

According to the embodiments, the display device including a first metal layer with high reflectivity and an excellent interface contact characteristic is provided.

### BRIEF DESCRIPTION OF THE DRAWINGS

FIG. 1 is a schematic cross-sectional view of a display area of a display device according to an embodiment.

FIG. 2 is a schematic cross-sectional view of a pad region of a display device according to an embodiment.

FIG. 3 is a schematic cross-sectional view of a first metal layer.

FIG. 4 is a schematic cross-sectional view showing generation of corrosion and oxidation reaction at a contact interface in case that a first metal layer includes aluminum.

FIG. 5 is a graph showing reflectivity of a first metal layer made of Zn-ITO/Ag/Zn-ITO with respect to a wavelength according to an embodiment.

FIG. 6 is a graph showing an XRD before/after a heat treatment of 250° C. of a Zn-ITO in which a content of Zn is about 18 at % and a content of Zn is about 20 at %.

### DETAILED DESCRIPTION OF THE EMBODIMENTS

In the following detailed description, embodiments of the disclosure have been shown and described, simply by way of illustration. As those skilled in the art would realize, the described embodiments may be modified in various different ways, all without departing from the spirit or scope of the disclosure.

The drawings and description are to be regarded as illustrative in nature and not restrictive, and like reference numerals designate like elements throughout the specification.

The size and thickness of each configuration shown in the drawings are arbitrarily shown for better understanding and ease of description, but the disclosure is not limited thereto. In the drawings, the thickness of layers, films, panels, regions, etc., are enlarged for clarity. The thicknesses of some layers and areas are exaggerated for convenience of explanation.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

The phrase “in a plan view” means viewing an object portion from the top, and the phrase “in a cross-sectional view” means viewing a cross-section of which the object portion is vertically cut from the side.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

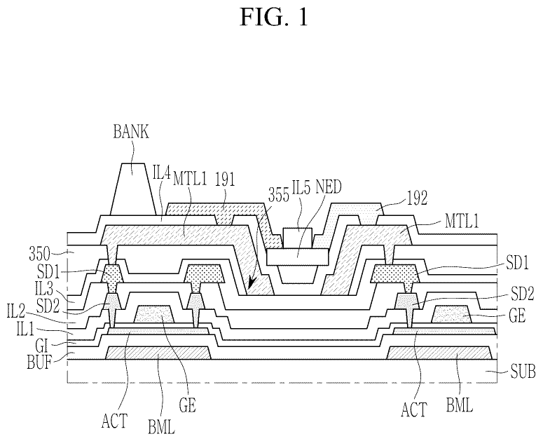

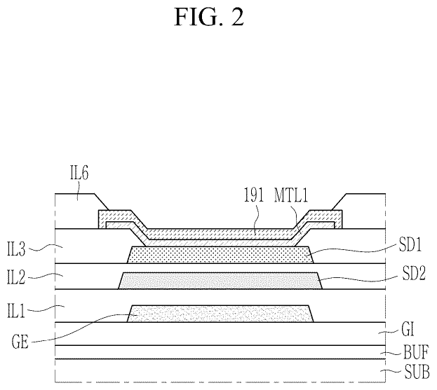

A display device according to an embodiment will now be described with reference to accompanying drawings. FIG. 1 is a schematic cross-sectional view of a display area of a display device according to an embodiment. FIG. 2 is a schematic cross-sectional view of a pad region of a display device according to an embodiment.

Referring to FIG. 1 and FIG. 2, a substrate SUB is provided. The substrate SUB may include at least one of polystyrene, polyvinyl alcohol, poly(methyl methacrylate), polyethersulfone, polyacrylate, polyetherimide, polyethylene naphthalate, polyethylene terephthalate, polyphenylene sulfide, polyarylate, polyimide, polycarbonate, cellulose triacetate, and cellulose acetate propionate. The substrate SUB may be a rigid substrate or a flexible substrate that may be bent, folded, or rolled. The substrate SUB may be a single layer or a multilayer. The substrate SUB may have a structure in which at least one base layer including sequentially stacked polymer resins and at least one inorganic layer are alternately stacked each other.

A light blocking layer BML may be disposed on the substrate SUB. The light blocking layer BML may include at least one of aluminum (Al), silver (Ag), magnesium (Mg), gold (Au), nickel (Ni), chromium (Cr), calcium (Ca), molybdenum (Mo), titanium (Ti), tungsten (W), copper (Cu), and a metal oxide, and may be a single layer or a multilayer including the same. For example, the light blocking layer BML may have a double layer of Ti/Cu, but the disclosure is not limited thereto.

A buffer layer BUF may be disposed on the light blocking layer BML. The buffer layer BUF may include at least one of a silicon oxide (SiOₓ), a silicon nitride (SiNₓ), a silicon oxynitride (SiOₓN_{y}), and amorphous silicon (Si).

A semiconductor layer ACT may be disposed on the buffer layer BUF. The semiconductor layer ACT may include an oxide semiconductor. The oxide semiconductor may include at least one of indium (In), tin (Sn), zinc (Zn), hafnium (Hf), and aluminum (Al). For example, the semiconductor layer ACT may include an indium-gallium-zinc oxide (IGZO). In an embodiment, the semiconductor layer ACT may include polycrystalline silicon.

A gate insulating layer GI may be disposed on the semiconductor layer ACT. The gate insulating layer GI may include at least one of a silicon oxide (SiOₓ), a silicon nitride (SiNₓ), a silicon oxynitride (SiOₓN_{y}), and amorphous silicon (Si).

A gate electrode GE may be disposed on the gate insulating layer GI. The gate electrode GE may include at least one of aluminum (Al), silver (Ag), magnesium (Mg), gold (Au), nickel (Ni), chromium (Cr), calcium (Ca), molybdenum (Mo), titanium (Ti), tungsten (W), copper (Cu), and a metal oxide, and may be a single layer or a multilayer including the same. For example, the gate electrode GE may be a double layer of Ti/Cu, but the disclosure is not limited thereto. The gate electrode GE may overlap the semiconductor layer ACT in a direction that is perpendicular to the substrate SUB.

A first insulating layer IL1 may be disposed on the gate electrode GE. The first insulating layer IL1 may include at least one of a silicon oxide (SiOₓ), a silicon nitride (SiNₓ), a silicon oxynitride (SiOₓN_{y}), and amorphous silicon (Si).

A second conductive layer SD2 may be disposed on the first insulating layer IL1. The second conductive layer SD2 may include at least one of aluminum (Al), silver (Ag), magnesium (Mg), gold (Au), nickel (Ni), chromium (Cr), calcium (Ca), molybdenum (Mo), titanium (Ti), tungsten (W), copper (Cu), and a metal oxide, and may be a single layer or a multilayer including the same. For example, the second conductive layer SD2 may be a double layer of Ti/Cu, but the disclosure is not limited thereto. In another embodiment, the second conductive layer SD2 may be a triple layer of Ti/Cu/ITO. The second conductive layer SD2 may contact the semiconductor layer ACT through openings formed in the first insulating layer IL1 and the gate insulating layer GI.

A second insulating layer IL2 may be disposed on the second conductive layer SD2. The second insulating layer IL2 may include at least one of a silicon oxide (SiOₓ), a silicon nitride (SiNₓ), a silicon oxynitride (SiOₓN_{y}), and amorphous silicon (Si).

A first conductive layer SD1 may be disposed on the second insulating layer IL2. The first conductive layer SD1 may include at least one of aluminum (Al), silver (Ag), magnesium (Mg), gold (Au), nickel (Ni), chromium (Cr), calcium (Ca), molybdenum (Mo), titanium (Ti), tungsten (W), copper (Cu), and a metal oxide, and may be a single layer or a multilayer including the same. For example, the first conductive layer SD1 may be a double layer of Ti/Cu. For example, the first conductive layer SD1 may include a first layer including titanium and a second layer including copper. However, the disclosure is not limited thereto. In another embodiment, the first conductive layer SD1 may be a triple layer of Ti/Cu/ITO.

The first conductive layer SD1 may contact the second conductive layer SD2 through the opening formed in the second insulating layer IL2. For example, the first conductive layer SD1 may be connected to the semiconductor layer ACT through the second conductive layer SD2. In an embodiment, the first conductive layer SD1 and the second insulating layer IL2 may be omitted.

A third insulating layer IL3 may be disposed on the first conductive layer SD1. The third insulating layer IL3 may include at least one of a silicon oxide (SiOₓ), a silicon nitride (SiNₓ), a silicon oxynitride (SiOₓN_{y}), and amorphous silicon (Si).

A cell barrier 350 may be disposed on the third insulating layer IL3. The cell barrier 350 may include an organic insulating material such as a general-purpose polymer such as poly(methyl methacrylate) (PMMA) or polystyrene (PS), a polymer derivative having a phenol-based group, an acryl-based polymer, an imide-based polymer, a polyimide, an acryl-based polymer, or a siloxane-based polymer. For example, the cell barrier 350 may include polyimide.

The cell barrier 350 may include an opening 355. As described below, an emission layer NED may overlap the opening 355 of the cell barrier 350 in a plan view. The emission layer NED may include a nanorod arranged in a direction. A detailed description of emission layer NED and a connection relationship will be described below.

A first metal layer MTL1 may be disposed on the cell barrier 350. The first metal layer MTL1 may contact the first conductive layer SD1 through openings penetrating the cell barrier 350 and the third insulating layer IL3. As shown in FIG. 1, the first metal layer MTL1 may be connected to the semiconductor layer ACT and the emission layer NED and may transmit a voltage from a transistor including the semiconductor layer ACT to the emission layer NED.

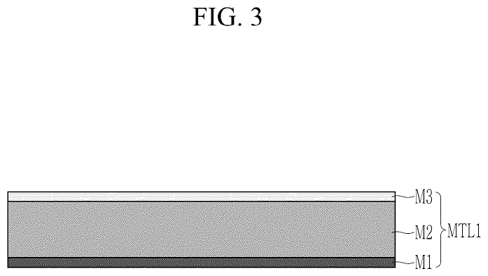

The first metal layer MTL1 may reflect light emitted by the emission layer NED. The first metal layer MTL1 may be a triple layer. FIG. 3 is a schematic cross-sectional view of the first metal layer MTL1. Referring to FIG. 3, the first metal layer MTL1 may include a first layer M1 including Zn-ITO, a second layer M2 including Ag, and a third layer M3 including Zn-ITO. Zn in Zn-ITO of the first layer M1 and the third layer M3 may be equal to or greater than about 10 at %. Zn-ITO of the first layer M1 and the third layer M3 may be amorphous, and may be maintained to be amorphous after the heat treatment at about 250° C. so the first layer M1 and the third layer M3 may be wet etched in a subsequent process. In case that the first metal layer MTL1 is a triple layer of Zn-ITO/Ag/Zn-ITO, the pad portion may have an excellent contact characteristic and a high reflection characteristic. An effect of the first metal layer MTL1 according to an embodiment will be described below.

The second layer M2 of the first metal layer MTL1 may be thicker than the first layer M1 of the first metal layer MTL1 and the third layer M3 of the first metal layer MTL1 in a thickness direction of the substrate SUB. This is because the second layer M2 including Ag may give an influence on the reflection characteristic, and the second layer M2 may have an excellent reflection characteristic in case that the second layer M2 is thick. The first layer M1 and the third layer M3 may increase an interface characteristic with adjacent layers, and the first layer M1 and the third layer M3 may not be thick.

For example, the thicknesses of the first layer M1 and the third layer M3 may be in a range of about 50 Å to about 300 Å. In case that the thicknesses of the first layer M1 and the third layer M3 are equal to or less than about 50 Å, a contact characteristic with other contacted layers may be deteriorated, and in case that the thicknesses are equal to or greater than about 300 Å, a reflectivity of the first metal layer MTL1 may be deteriorated.

The thickness of the second layer M2 may be in a range of about 500 Å to about 2000 Å. In case that the thickness of the second layer M2 is less than about 500 Å, the first metal layer MTL1 may not have a sufficient reflection characteristic, and in case that the thickness of the second layer M2 is greater than about 2000 Å, the first metal layer MTL1 may become very thick, which may be undesirable.

Referring to FIG. 1, a fourth insulating layer IL4 may be disposed on the first metal layer MTL1. The fourth insulating layer IL4 may include at least one of a silicon oxide (SiOₓ), a silicon nitride (SiNₓ), a silicon oxynitride (SiOₓN_{y}), and amorphous silicon (Si).

A first electrode 191 may be disposed on the fourth insulating layer IL4. The first electrode 191 may contact the first metal layer MTL1 through an opening of the fourth insulating layer IL4. A second electrode 192 and the first electrode 191 may be disposed on a same layer. The first electrode 191 and the second electrode 192 may include a transparent conductive oxide, for example, an indium tin oxide (ITO).

Referring to FIG. 1, an emission layer NED may be disposed on the fourth insulating layer IL4. The emission layer NED may overlap the opening 355 of the cell barrier 350 in a plan view. The emission layer NED may include a nanorod. The nanorod may be arranged in a direction, may include an inorganic material, and may emit light when receiving a voltage.

Referring to FIG. 1, the first electrode 191 may be connected to a side of the emission layer NED, and the second electrode 192 may be connected to another side of the emission layer NED. The second electrode 192 may be electrically connected to another semiconductor layer ACT. A fifth insulating layer IL5 may be disposed on an upper portion of the emission layer NED to insulate the first electrode 191 and the second electrode 192 from each other. A bank may be disposed on the fourth insulating layer IL4.

FIG. 1 schematically shows a cross-section of a display area of a display device, and FIG. 2 is a schematic cross-sectional view of a pad region of a display device. Referring to FIG. 2, a buffer layer BUF and a gate insulating layer GI may be sequentially disposed on the substrate SUB. Descriptions of the corresponding constituent elements are the same as what is described with reference to FIG. 1 so they will be omitted. For example, the pad region of FIG. 2 and the display area of FIG. 1 may be formed by a same process, and the materials and the thicknesses of respective layers in the display area and the pad region may be the same.

Referring to FIG. 2, a gate electrode GE, a first insulating layer IL1, a second conductive layer SD2, a second insulating layer IL2, and a first conductive layer SD1 may be sequentially disposed on the gate insulating layer GI. Descriptions of the corresponding constituent elements are the same as what is described with reference to FIG. 1 so they will be omitted.

The first conductive layer SD1 may include at least one of aluminum (Al), silver (Ag), magnesium (Mg), gold (Au), nickel (Ni), chromium (Cr), calcium (Ca), molybdenum (Mo), titanium (Ti), tungsten (W), copper (Cu), and a metal oxide, and may be a single layer or a multilayer including the same. For example, the first conductive layer SD1 may be a double layer of Ti/Cu. In another embodiment, the first conductive layer SD1 may be a triple layer of Ti/Cu/ITO.

Referring to FIG. 2, a third insulating layer IL3 may be disposed on the first conductive layer SD1. The third insulating layer IL3 may include an opening overlapping the first conductive layer SD1 in a plan view.

A first metal layer MTL1 may be disposed on the third insulating layer IL3. The first metal layer MTL1 may contact the first conductive layer SD1 in the opening of the third insulating layer IL3. The first metal layer MTL1 may be a triple layer. As described above, the first metal layer MTL1 may include a first layer M1 including Zn-ITO, a second layer M2 including Ag, and a third layer M3 including Zn-ITO.

A first electrode 191 may be disposed on the first metal layer MTL1. The first electrode 191 may include an indium tin oxide (ITO). As shown in FIG. 2, the first conductive layer SD1, the first metal layer MTL1, and the first electrode 191 may contact each other in a pad portion. Hence, contact characteristics at respective interfaces may be important.

As shown in FIG. 2, a sixth insulating layer IL6 may be disposed on the first electrode 191. The sixth insulating layer IL6 may include at least one of a silicon oxide (SiOₓ), a silicon nitride (SiNₓ), a silicon oxynitride (SiOₓN_{y}), and amorphous silicon (Si).

FIG. 3 is a schematic cross-sectional view of a first metal layer MTL1. Referring to FIG. 3, the first metal layer MTL1 may include a first layer M1 including Zn-ITO, a second layer M2 including Ag, and a third layer M3 including Zn-ITO. Thicknesses of the first layer M1 and the third layer M3 may be in a range of about 50 Å to about 300 Å, and a thickness of the second layer M2 may be in a range of about 500 Å to about 2000 Å.

The second layer M2 may include Ag, and the Ag may have the greatest reflection characteristic from among the metals so the first metal layer MTL1 may have an excellent reflection characteristic.

The first layer M1 and the third layer M3 may include Zn-ITO. The third layer M3 may contact the first electrode 191 including an ITO. As the third layer M3 includes Zn-ITO, the third layer M3 may contact the first electrode 191 including an ITO. Therefore, the first metal layer MTL1 may contact the first electrode 191.

The first layer M1 may contact the first conductive layer SD1. The first conductive layer SD1 may be a double layer of Ti/Cu, or may be a triple layer of Ti/Cu/ITO. The first layer M1 may include Zn-ITO so the first layer M1 may contact the second conductive layer SD2 made of Ti/Cu or Ti/Cu/ITO.

In case that the first metal layer MTL1 includes aluminum, the aluminum may have a defect of increasing the corrosion and oxidation reaction because of the ITO and a standard reduction potential difference. The ITO and the aluminum may not make a good ohmic contact, and may be melted by a solution such as a KOH or a TMAH used in a subsequent process in case that the aluminum is exposed on an upper portion.

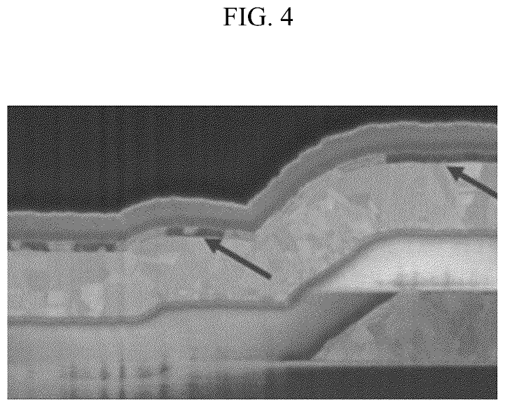

FIG. 4 is a schematic cross-sectional view showing generation of corrosion and oxidation reaction in case that the first metal layer MTL1 includes aluminum. It is found that the corrosion and oxidation are generated at the interface as shown in the region marked with arrows in FIG. 4.

However, in the display device according to an embodiment, the first metal layer MTL1 may include a first layer M1 including Zn-ITO, a second layer M2 including Ag, and a third layer M3 including Zn-ITO. Therefore, as described above, the display device may have a high reflection characteristic, and may have an excellent contact characteristic at the interface of the first metal layer MTL1 and first electrode 191, and the first metal layer MTL1 and the first conductive layer SD1.

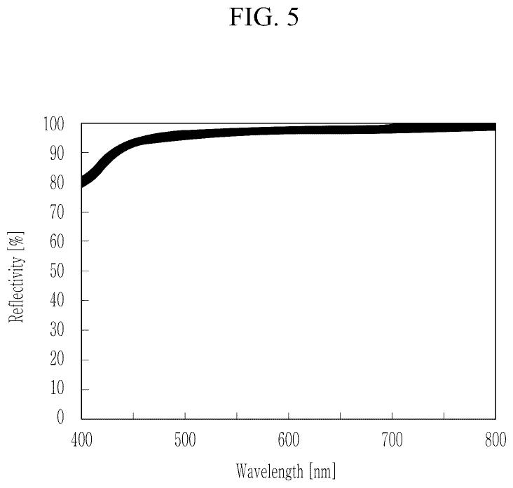

FIG. 5 is a graph showing reflectivity of a first metal layer MTL1 made of Zn-ITO/Ag/Zn-ITO with respect to a wavelength according to an embodiment. Referring to FIG. 5, it is found that the first metal layer MTL1 of Zn-ITO/Ag/Zn-ITO has excellent reflectivity in an entire wavelength region of visible rays. For example, it is found that the reflectivity is 80% in the wavelength region of about 400 nm to about 800 nm.

In an embodiment, Zn in Zn-ITO of the first layer M1 and the third layer M3 may be equal to or greater than about 10 at %. For example, Zn may be in a range of about 18 at % to about 20 at % of the first layer M1 and the third layer M3. The Zn-ITO having the content of Zn may be maintained to be amorphous after the heat treatment of about 250° C. is performed, and a wet etching may be performed in a subsequent process.

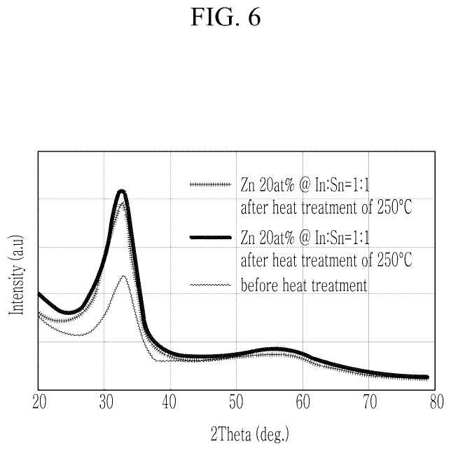

FIG. 6 is a graph showing an XRD before/after a heat treatment of about 250° C. of a Zn-ITO in which a content of Zn is about 18 at % and a content of Zn is about 20 at %. Referring to FIG. 6, it is found that the Zn-ITO may be maintained to be amorphous after the heat treatment of about 250° C. is performed. Hence, the Zn-ITO may be wet etched, and a subsequent process may be performed. For example, as the ITO having no Zn is crystalline, it was difficult to perform a wet etching in the subsequent process. However, as the Zn-ITO according to an embodiment is amorphous, a dry etching may be readily performed.

Table 1 shows estimation results of reflectivity, states of contacting the ITO, and etching characteristics of subsequent processes while varying compositions of the first metal layer MTL1.

TABLE 1

| | Reflectivity | | Etching |
|---|---|---|---|
| Compositions | (@450 nm) | States of | characteristic |
| of first metal | Ref: | contacting | of subsequent |
| layer MTL1 | A1 100% | the ITO | processes |
| A1 | 100% | Not possible | Possible |
| | | (Non ohmic contact | |
| | | characteristic) | |
| ITO/Ag/ITO | 103% | Possible | Not possible |
| | | | (because |
| | | | of poly-ITO) |
| Zn-ITO/Ag/ | 103% | Possible | Possible |
| Zn-ITO | | | |

Referring to Table 1, in case that the first metal layer includes aluminum, it fails to perform an ohmic contact to the ITO so the contact at the interface is unstable. Further, in case that the first metal layer includes ITO/Ag/ITO, reflectivity is increased compared to the case in which the first metal layer includes aluminum, but the etching is impossible in the subsequent process because of a polycrystalline ITO. In the case of the first metal layer with the structure of Zn-ITO/Ag/Zn-ITO according to an embodiment, the reflectivity is increased compared to the case that the first metal layer includes aluminum, the first metal layer may contact the ITO, and the first metal layer is maintained to be amorphous as found in FIG. 5, so the first metal layer may be etched in the subsequent process. For example, in the display device according to an embodiment, the first metal layer MTL1 may have a triple layer of Zn-ITO/Ag/Zn-ITO. Hence, the first metal layer MTL1 may stably contact the first electrode 191 and the first conductive layer SD1 on the pad portion, and the first metal layer MTL1 may include Ag so it has a high reflectivity, and also has the amorphous characteristic after Zn-ITO undergoes a heat treatment, so the first metal layer MTL1 may be easily etched in the subsequent process. The display device including the first metal layer MTL1 may increase a reflectivity to a high level, and may simplify the manufacturing process as an additional mask process required to avoid the contact of the ITO of the first electrode and the aluminum in case that the first metal layer MTL1 includes aluminum is not required. Further, the first metal layer MTL1 may have a damage-free stable structure for the TMAH or KOH that is a developing solution of Zn-ITO/Ag/Zn-ITO, so the subsequent process may be readily performed.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a transistor disposed on a substrate;
a first conductive layer electrically connected to the transistor;
a first metal layer electrically connected to the first conductive layer;
a first electrode electrically connected to the first metal layer; and
an emission layer electrically connected to the first electrode,
wherein the first metal layer includes a first layer including Zn-ITO, a second layer including Ag, and a third layer including Zn-ITO.

2. The display device of claim 1, wherein
the display device includes a display area and a pad region, and
the first conductive layer, the first metal layer, and the first electrode contact each other in the pad region.

3. The display device of claim 2, wherein
the first conductive layer includes a first layer including titanium and a second layer including copper, and
the second layer of the first conductive layer contacts the first layer of the first metal layer.

4. The display device of claim 1, wherein
the first conductive layer includes a first layer including titanium, a second layer including copper, and a third layer including an indium tin oxide, and
the third layer of the first conductive layer contacts the first layer of the first metal layer.

5. The display device of claim 2, wherein
the first electrode includes an indium tin oxide, and
the third layer of the first metal layer contacts the first electrode.

6. The display device of claim 1, wherein the second layer of the first metal layer is thicker than the first layer of the first metal layer and the third layer of the first metal layer in a thickness direction of the substrate.

7. The display device of claim 1, wherein a thickness of the first layer of the first metal layer is in a range of about 50 Å to about 300 Å in a thickness direction of the substrate.

8. The display device of claim 7, wherein a thickness of the second layer of the first metal layer is in a range of about 500 Å to about 2000 Å in a thickness direction of the substrate.

9. The display device of claim 8, wherein a thickness of the third layer of the first metal layer is in a range of about 50 Å to about 300 Å in the thickness direction.

10. The display device of claim 1, wherein a content of Zn included in Zn-ITO of the first layer and the third layer is equal to or greater than about 10 at %.

11. The display device of claim 1, wherein a content of Zn included in Zn-ITO of the first layer and the third layer is in a range of about 18 at % to about 20 at %.

12. The display device of claim 1, wherein Zn-ITO included in the first layer and the third layer is amorphous.

13. The display device of claim 1, wherein Zn-ITO included in the first metal layer is amorphous in case that a heat treatment of about 250° C. is performed.

14. The display device of claim 1, wherein the first metal layer is not etched by TMAH and KOH.

15. The display device of claim 1, wherein a reflectivity of the first metal layer on a wavelength in a range of about 400 nm to about 800 nm is equal to or greater than about 80%.

16. The display device of claim 1, wherein the emission layer includes a nanorod.

17. The display device of claim 1, wherein
the transistor includes a semiconductor layer and a gate electrode, and
the display device further comprises a second conductive layer disposed between the semiconductor layer and the first conductive layer and electrically connecting the semiconductor layer and the first conductive layer.

18. The display device of claim 1, further comprising:
a cell barrier disposed between the first conductive layer and the first metal layer,
wherein the cell barrier includes an opening overlapping the emission layer in a plan view.

19. The display device of claim 1, wherein light emitted by the emission layer is reflected by the first metal layer.

20. The display device of claim 17, wherein the semiconductor layer includes an oxide semiconductor.
